(19) United States
(12) Patent Application Publication
(10) Pub. No.: US 2024/0304505 A1
(43) Pub. Date: Sep. 12, 2024

(54) INSERT-MOLDED ARTICLE AND METHOD FOR MANUFACTURING INSERT-MOLDED ARTICLE

(71) Applicant: FUJI ELECTRIC CO., LTD., Kawasaki-shi (JP)

(72) Inventor: Hisato INOKUCHI, Kawasaki-shi (JP)

(73) Assignee: FUJI ELECTRIC CO., LTD., Kawasaki-shi (JP)

(21) Appl. No.: 18/428,358

(22) Filed: Jan. 31, 2024

(30) Foreign Application Priority Data
Mar. 6, 2023 (JP) 2023-033508

(51) Int. Cl. H01L 23/057; H01L 21/48

(52) U.S. Cl. CPC H01L 23/057; H01L 21/4817

(57) ABSTRACT

An insert-molded article includes a resin portion, and a terminal having a first portion extending in a first direction from the resin portion to be adjacent to the resin portion at a first side of the resin portion, a second portion extending in a second direction different from the first direction from the resin portion to be adjacent to the resin portion at a second side of the resin portion that is different from the first side, and a tip portion connected to one of the first and second portions. The first and second portions have rigidities that are higher than a rigidity of the tip portion.

### CROSS-REFERENCE TO RELATED APPLICATION

This application is based upon and claims the benefit of priority to Japanese Patent Application No. 2023-033508, Filed on Mar. 6, 2023, the entire contents of which are incorporated herein by reference.

### BACKGROUND OF THE INVENTION

### 1. Technical Field

The present invention relates to an insert-molded article including a terminal and a resin portion, and a method for manufacturing the insert-molded article.

### 2. Description of the Related Art

Conventionally, a semiconductor device includes a substrate having a semiconductor element such as an insulated gate bipolar transistor (IGBT), and each portion is electrically connected by a terminal (see, for example, JP 2015-032727 A, JP 2020-022239 A, and JP H09-321217 A).

In addition, in order to prevent deformation and the like of a terminal due to the injection pressure of a resin, a method has been proposed in which the terminal is integrated with a primary resin in a primary molding die and then integrated with a secondary resin in a secondary molding die (see, for example, JP 2001-293744 A).

### SUMMARY OF THE INVENTION

As described above, in a case where the molding of the resin for the terminal is divided into two times of the primary molding and the secondary molding, it takes time, labor, and cost for two times as compared with a case where molding is performed only once. Therefore, it is desirable to improve the positional accuracy of the terminal after molding of the resin even when molding is performed only once.

An object of the present invention is to provide an insert-molded article capable of improving the positional accuracy of a terminal after molding of a resin, and a method for manufacturing the insert-molded article.

In one aspect, an insert-molded article includes a resin portion and a terminal having both ends extending from the resin portion, in which the terminal has higher rigidity at a first portion adjacent to the resin portion outside the resin portion and a second portion adjacent to the resin portion on a side opposite to the first portion than at a tip portion of the terminal on at least one end side.

In another aspect, a method for manufacturing an insert-molded article is a method for manufacturing an insert-molded article including a resin portion and a terminal having both ends extending from the resin portion, the method including: supporting each of a first portion and a second portion of the terminal by a molding die, the first portion and the second portion having higher rigidity than a tip portion of the terminal on at least one end side; and supplying a resin to the terminal between the first portion and the second portion in a state where the first portion and the second portion are supported by the molding die, and curing the resin.

According to the above aspects, the positional accuracy of the terminal after molding of the resin can be improved.

### BRIEF DESCRIPTION OF THE DRAWINGS

FIG. 1 is a perspective view illustrating an insert-molded article according to an embodiment;

FIG. 2 is a perspective view illustrating a terminal in an embodiment;

FIG. 3 is a right side view illustrating the terminal in an embodiment;

FIG. 4 is a plan view illustrating a semiconductor device in an embodiment; and

FIG. 5 is a plan view illustrating a molding die (the terminal is upside down) in an embodiment.

### DETAILED DESCRIPTION

Hereinafter, an insert-molded article and a method for manufacturing the insert-molded article according to an embodiment of the present invention will be described with reference to the drawings. Note that the present invention is not limited to the embodiment described below, and can be appropriately modified and implemented within the scope not changing the gist thereof.

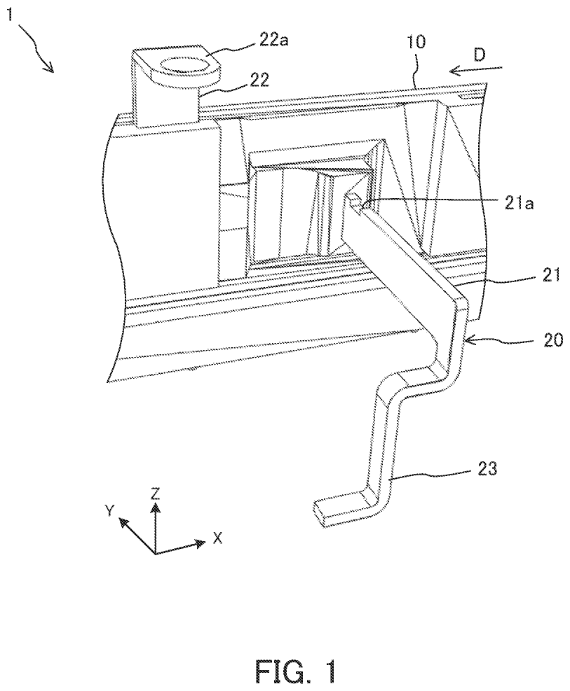

FIG. 1 is a perspective view illustrating an insert-molded article 1 according to an embodiment.

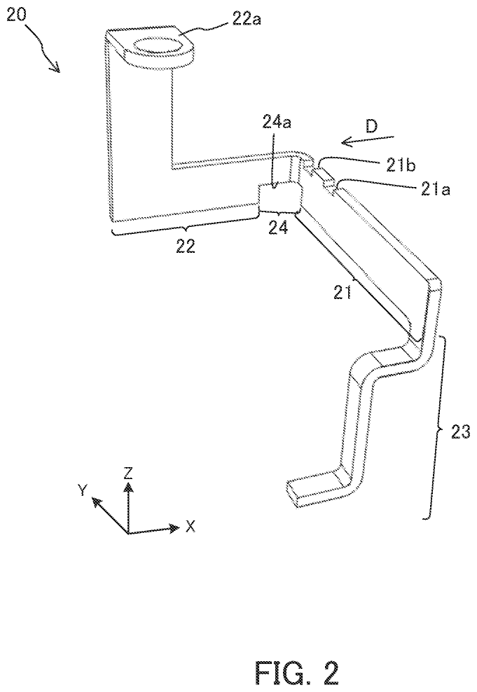

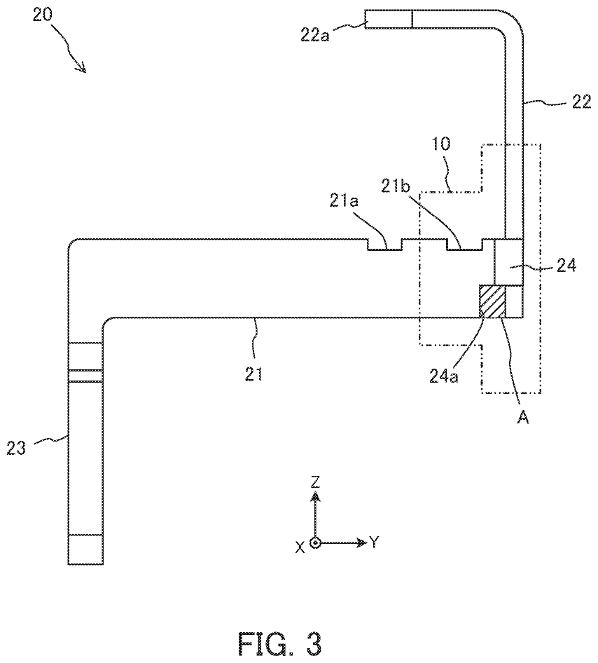

FIGS. 2 and 3 are a perspective view and a right side view illustrating a terminal 20.

Note that an X direction, a Y direction, and a Z direction illustrated in FIGS. 1 to 3 and FIGS. 4 and 5 described later are examples for convenience of description, but for example, the X direction and the Y direction are horizontal directions, and the Z direction is a vertical direction. In some cases, the X direction may be referred to as a left and right direction, the Y direction may be referred to as a front and rear direction, and the Z direction may be referred to as an up and down direction, in which the positive side in the X direction is defined as a right direction, the positive side in the Y direction is defined as being rearward, and the positive side in the Z direction is defined as being upward.

The insert-molded article 1 illustrated in FIG. 1 includes a resin portion 10 and the terminal 20 having both ends extending from the resin portion 10.

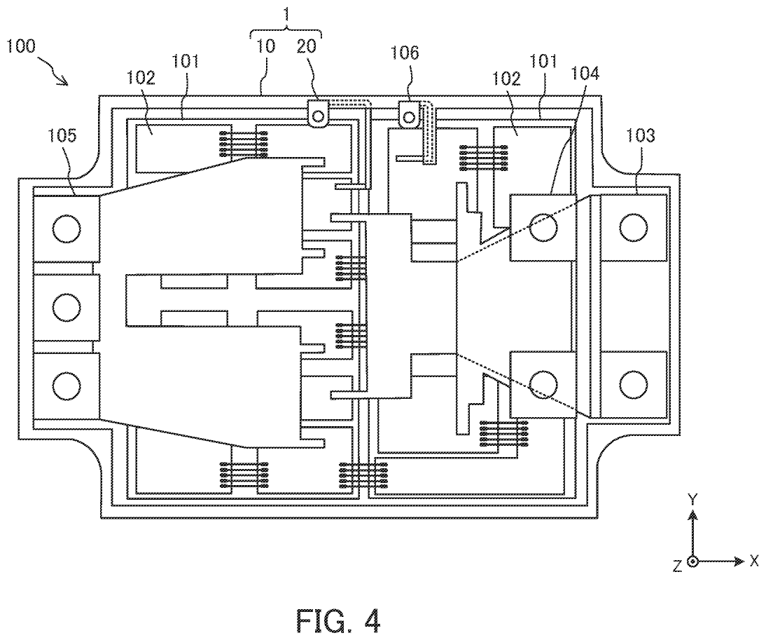

The resin portion 10 is used, for example, as a case member of a semiconductor device 100 illustrated in FIG. 4 described later. As a resin material of the resin portion 10, in a case where the resin portion 10 is used as a case member of the semiconductor device 100, any insulating resin can be selected from, for example, polyphenylene sulfide (PPS), polybutylene terephthalate (PBT), polybutyl acrylate (PBA), polyimide (PA), acrylonitrile butadiene styrene (ABS), liquid crystal polymer (LCP), polyether ether ketone (PEEK), polybutylene succinate (PBS), urethane, and silicon. In addition, the resin to be selected may be a mixture of two or more types of resin. The resin may contain a filler (for example, a glass filler) for improvement in strength or functionality.

The terminal 20 is, for example, a metal plate formed of a metal material such as a copper material, a copper alloy-based material, an aluminum alloy-based material, or an iron alloy-based material. The terminal 20 is integrally molded (insert-molded) with the resin portion 10 so as to be embedded in the resin portion 10 except for the both ends.

As illustrated in FIG. 2, the terminal 20 includes a first portion 21, a second portion 22, a board-side tip portion 23, and an easily-deformable portion 24. These portions are integrally and continuously provided, for example, in the order of the board-side tip portion 23, the first portion 21, the easily-deformable portion 24, and the second portion 22.

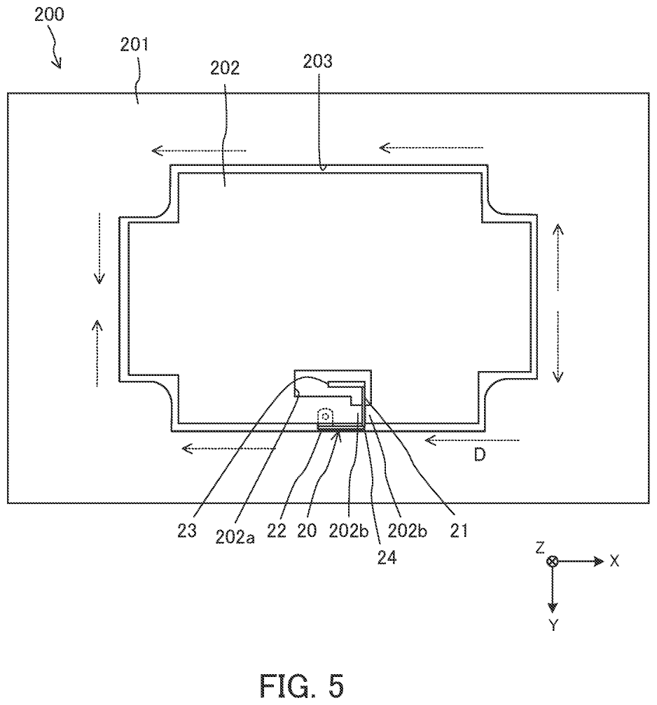

As illustrated in FIG. 1, the first portion 21 is adjacent to the resin portion 10 in front (the negative side in the Y direction (first direction)) of and outside the resin portion 10. The first portion 21 is a plate-like portion extending in a YZ plane (third plane). The first portion 21 preferably extends from outside to inside the resin portion 10. The first portion 21 is supported by a molding die 200 illustrated in FIG. 5 described later at the time of molding (injection molding) the resin portion 10 outside the resin portion 10. A length of the first portion 21 in an extending direction (Y direction) is longer outside the resin portion 10 than inside the resin portion 10. Therefore, an area of a surface (YZ plane (third cross-sectional area) illustrated in FIG. 3) orthogonal to a plate thickness direction (X direction) in the first portion 21 is larger outside the resin portion 10 than inside the resin portion 10. In addition, a volume of the first portion 21 is larger outside the resin portion 10 than inside the resin portion 10. As will be described later, in the surface (YZ plane illustrated in FIG. 3) orthogonal to the plate thickness direction (X direction=injection direction D) in the first portion 21, the first portion 21 is supported by a pair of support portions 202b (molding die 200) illustrated in FIG. 5 in a region having a larger area than a region to which the resin is supplied.

An external cut-away part 21a located outside the resin portion 10 and an internal cut-away part 21b located inside the resin portion 10 are provided in an upper portion of the first portion 21. Note that the external cut-away part 21a and the internal cut-away part 21b, and a cut-away part 24a of the easily-deformable portion 24 described later may be formed simultaneously at the time of forming the terminal 20 by, for example, pressing, rolling, or the like, or may be separately formed by machining such as laser machining or wire electrical discharge machining after the formation of the terminal 20.

In the first portion 21, instead of the external cut-away part 21a and the internal cut-away part 21b, a protrusion protruding in the up and down direction from the first portion 21, or a cut- away part or a protrusion located on the left or right surface (surface on the positive side or the negative side in the X direction) of the first portion 21 may be provided. These cut-away parts (including the external cut-away part 21a and the internal cut-away part 21b) and protrusions may be provided in the second portion 22.

The second portion 22 is located on the side opposite to the first portion 21 with the easily-deformable portion 24, which is a bent portion, interposed therebetween, extends from the easily-deformable portion 24 in the left direction (the negative side in the X direction (second direction)), which is an example of a first direction and which constitutes a first-second portion, and then is bent to extend upward (the positive side in the Z direction (third direction)), which is an example of a second direction perpendicular to the first direction and which constitutes a second-second portion, so that a part of the portion extending upward is exposed from the resin portion 10. In addition, the second portion 22 includes an outer-side tip portion 22a bent and extending forward (the negative side in the Y direction) from an upper end. The outer-side tip portion 22a is electrically connected to, for example, an external conductor disposed outside the semiconductor device 100 (see FIG. 4) by bolt fixing. The second portion 22 is adjacent to the resin portion 10 outside the resin portion 10 on the side opposite to the first portion 21. The second portion 22 is a plate-like portion extending in an XZ plane except for the outer-side tip portion 22a. The second portion 22 preferably extends from outside to inside the resin portion 10. The second portion 22 is supported by the molding die 200 illustrated in FIG. 5 described later at the time of molding (injection molding) the resin portion 10 outside the resin portion 10.

The board-side tip portion 23 is an example of a tip portion of the terminal 20, extends in the left direction (the negative side in the X direction) from a front (the negative side in the Y direction) end portion of the first portion 21, is bent to extend downward (the negative side in the Z direction), and is bent again to extend in the left direction. The board-side tip portion 23 is bonded to a circuit board 101 of the semiconductor device 100 illustrated in FIG. 4 described later with a bonding material such as solder.

A width (length in a width direction (Y direction) orthogonal to the extending direction and the plate thickness direction) of the board-side tip portion 23 is shorter than a width (Z direction) of the first portion 21 and a width (Z direction) of the second portion 22. Since the plate thickness of the terminal 20 is constant, the first portion 21 and the second portion 22 have a larger cross-sectional area orthogonal to the extending direction of the terminal 20 than the board-side tip portion 23. Therefore, the first portion 21 and the second portion 22 have higher rigidity than the board-side tip portion 23. Note that in order to make the rigidity of the first portion 21 and the second portion 22 higher than the rigidity of the board-side tip portion 23 in this manner, the thickness of the first portion 21 and the second portion 22 may be made larger than the thickness of the board-side tip portion 23, processing such as heat treatment may be performed on one or both of the first and second portions 21 and 22 and the board-side tip portion 23, or bent portions bent by, for example, 90 degrees may be provided at the ends of the first portion 21 and the second portion 22 in the width direction.

The easily-deformable portion 24 is an example of a third portion, and is a bent portion located between the first portion 21 and the second portion 22 as described above. The easily-deformable portion 24 is connected to the first portion 21 and the second portion 22 such that the extending direction of the first portion 21 and the extending direction of the second portion 22 are orthogonal to each other. The cut-away part 24a is provided at a lower end of the easily-deformable portion 24. As a result, since a width of the easily-deformable portion 24 becomes a narrow portion by providing the cut-away part 24a, the easily-deformable portion 24 has a smaller cross-sectional area orthogonal to the extending direction than the first portion 21 and the second portion 22. Therefore, the easily-deformable portion 24 can be said to be a portion (portion having lower rigidity) that is particularly more easily deformed at the time of molding than other adjacent portions (the first portion 21 and the second portion 22). In addition, in order to make the easily-deformable portion 24 more deformable than other adjacent portions, the thickness of the easily-deformable portion 24 may be made thinner than the thickness of the first portion 21 and the second portion 22, processing such as heat treatment may be performed on one or both of the easily-deformable portion 24 and the first and second portions 21 and 22, or bent portions bent by, for example, 90 degrees may be provided at the ends of the first portion 21 and the second portion 22 in the width direction.

A resin is supplied to the terminal 20 in the injection direction D on the negative side in the X direction illustrated in FIGS. 1, 2, and 5 at the time of injection molding. Then, as illustrated in FIG. 3, in the easily-deformable portion 24, which becomes a narrow portion by providing the cut-away part 24a, the area (area in the YZ plane) orthogonal to the injection direction D in a portion of the terminal 20 to which the resin is supplied is reduced by the region A indicated by hatching. As a result, the terminal 20 is less likely to receive the injection pressure of the resin at the time of molding the resin portion 10. In the portion adjacent to the right of the region A in FIG. 3, the second portion 22 is exposed by providing the cut-away part 24a, but the exposed portion of the second portion 22 is not a surface orthogonal to the plate thickness direction of the second portion 22 but an end surface of the second portion 22, and thus it can be said that the portion is hardly deformed by the injection pressure. Note that the narrow portion reducing the area orthogonal to the injection direction D in the portion of the terminal 20 to which the resin is supplied may be provided at a portion other than the easily-deformable portion 24. For example, in the example of FIG. 3, it can be said that the internal cut-away part 21b of the first portion 21 also reduces the area orthogonal to the injection direction D in the portion to which the resin is supplied. However, by providing the cut-away part 24a in the easily-deformable portion 24, which is the bent portion, the easily-deformable portion 24 becomes a narrow portion and is easily deformed, and the area orthogonal to the injection direction D can be reduced and the injection pressure can be hardly received, so that the above-described narrow portion is preferably the easily-deformable portion 24.

The semiconductor device 100 illustrated in FIG. 4 is merely an example, but is applied to, for example, a power conversion device such as a power control unit, and is a power semiconductor module constituting an inverter circuit.

The semiconductor device 100 includes the resin portion 10 (case member) and the terminal 20, which are the above-described insert-molded article 1, one or more circuit boards 101, one or more semiconductor elements 102 disposed on the circuit board 101, a first lead frame 103, a second lead frame 104, a third lead frame 105, a terminal 106, and a sealing resin (not illustrated) injected into the resin portion 10.

The circuit board 101 includes, for example, a direct copper bonding (DCB) substrate, an active metal brazing (AMB) substrate, or a metal base substrate. For example, the circuit board 101 includes an insulating plate, a conductor located above the insulating plate, and a heat sink located below the insulating plate. A heat dissipation fin (not illustrated) is disposed below the circuit board 101.

The semiconductor element 102 is bonded at an upper surface of the circuit board 101 by, for example, solder. Note that examples of the semiconductor element 102 include a switching element such as an insulated gate bipolar transistor (IGBT) or a power metal oxide semiconductor field effect transistor (MOSFET), and a diode such as a free wheeling diode (FWD).

The resin portion 10 used as the case member is formed in a frame shape. In the resin portion 10, the first lead frame 103, the second lead frame 104, and the third lead frame 105 are held by a holding portion (not illustrated).

Each of the first lead frame 103, the second lead frame 104, and the third lead frame 105 constitutes a main terminal bonded at one end to the circuit board 101 by, for example, solder or an ultrasonic bonding portion and connected at the other end to an external conductor (not illustrated).

Similarly to the terminal 20, the terminal 106 preferably includes the first portion 21, the second portion 22, the board-side tip portion 23, and the easily-deformable portion 24 described above, and functions as a control terminal together with the terminal 20.

Note that the insert-molded article 1 (the resin portion 10 and the terminal 20) is desirably used for the semiconductor device 100, but may be used for applications other than the semiconductor device 100.

FIG. 5 is a plan view illustrating the molding die 200. Note that in FIG. 5, the terminal 20 is disposed upside down from that in FIGS. 1 to 4.

The molding die 200 includes a die main body 201, a nest 202, and an upper die (not illustrated) disposed on an upper portion of the die main body 201.

The die main body 201 has a rectangular parallelepiped shape provided with a recess at the center of an upper surface. The nest 202 is inserted from above into the recess at the center of the upper surface of the die main body 201. A cavity 203 is formed between the die main body 201 and the nest 202. The resin for molding the resin portion 10 flows into the cavity 203 via a sprue, a runner, or a gate (not illustrated) as indicated by dotted arrows in FIG. 5. Note that the injection direction D of the resin supplied to the terminal 20 is the negative side in the X direction in a region where the terminal 20 is disposed.

The nest 202 includes an accommodating portion 202a opened in the upper surface and the pair of support portions 202b supporting the first portion 21 of the terminal 20. The accommodating portion 202a accommodates the board-side tip portion 23 of the terminal 20. The pair of support portions 202b is located on both sides with a gap between the accommodating portion 202a and the cavity 203, and sandwiches and supports the first portion 21. In a state where the pair of support portions 202b supports the first portion 21, a part of the nest 202 is desirably inserted into the external cut-away part 21a of the first portion 21 illustrated in FIG. 1. Note that in the surface orthogonal to the injection direction D in the first portion 21, the area of the region supported by the pair of support portions 202b (molding die 200) is preferably larger than the area of the region of the first portion 21 to which the resin is supplied (see the resin portion 10 illustrated in FIG. 3).

The nest 202 (alternatively, the gap in the up and down direction between the nest 202 and the die main body 201) is provided with a groove (not illustrated) into which the second portion 22 of the terminal 20 is inserted, and both side portions of the nest 202 separated by the groove sandwich and support the second portion 22.

As described above, the terminal 20 is supported by the molding die 200 at the first portion 21 and the second portion 22 having higher rigidity than the board-side tip portion 23, and the resin is supplied between the first portion 21 and the second portion 22 (including a part of the first portion 21 and a part of the second portion 22) in the cavity 203. Then, the supplied resin is cured by, for example, forced cooling or natural cooling. Note that the resin does not flow into the accommodating portion 202a of the nest 202.

In the present embodiment described above, the insert-molded article 1 includes the resin portion 10 and the terminal 20 having both ends extending from the resin portion 10, and the terminal 20 has higher rigidity at the first portion 21 adjacent to the resin portion 10 outside the resin portion 10 and the second portion 22 adjacent to the resin portion 10 on the side opposite to the first portion 21 than at the board-side tip portion 23 (an example of a tip portion of the terminal 20 on at least one end side).

In addition, from the viewpoint of a method for manufacturing the insert-molded article 1, the method for manufacturing the insert-molded article 1 is a method for manufacturing the insert-molded article 1 including the resin portion 10 and the terminal 20 having both ends extending from the resin portion 10, the method including: supporting each of the first portion 21 and the second portion 22 having higher rigidity than the board-side tip portion 23 (an example of the tip portion of the terminal 20 on at least one end side) by the molding die 200 (supporting step); and supplying the resin to the terminal 20 between the first portion 21 and the second portion 22 in a state where the first portion 21 and the second portion 22 are supported by the molding die 200 and curing the resin (supplying and curing step).

According to the insert-molded article 1 and the method for manufacturing the insert-molded article 1, since the terminal 20 can be supported by the molding die 200 at the first portion 21 and the second portion 22 having relatively high rigidity, deformation of the terminal 20 at the time of molding can be suppressed. Therefore, the positional accuracy of the terminal 20 after molding of the resin can be improved. Therefore, as compared with a mode in which molding of the resin is divided into primary molding and secondary molding in order to improve the positional accuracy of the terminal 20 after molding of the resin, it is possible to avoid the time, labor, and cost required for two times of molding.

In addition, in the present embodiment, the terminal 20 has a larger cross-sectional area orthogonal to the extending direction of the terminal 20 at the first portion 21 and the second portion 22 than at the board-side tip portion 23. Specifically, a cross-sectional area (first cross-sectional area) of the first portion 21 in an XZ plane (first plane) that is orthogonal to the extending direction Y and a cross-sectional area (second cross-sectional area) of the second portion 22 in a YZ plane (second plane) that is orthogonal to the extending direction X are greater than a cross-sectional area of the board-side tip portion 23 in a plane orthogonal to an extending direction of the tip portion 23.

Therefore, for example, by increasing the cross-sectional areas of the first portion 21 and the second portion 22 with a simple configuration in which the widths of the first portion 21 and the second portion 22 are longer than the width of the board-side tip portion 23, the rigidity of the first portion 21 and the second portion 22 can be enhanced.

In addition, in the present embodiment, the terminal 20 includes, inside the resin portion 10, the easily-deformable portion 24, which is more easily deformed than other adjacent portions (for example, the first portion 21 and the second portion 22) of the terminal 20.

By the way, when the terminal 20 is disposed in the molding die 200, the terminal 20 is deformed due to a deviation (difference in quality) between the shape of the terminal 20 and the shape of the molding die 200. In the present embodiment, the deformed portion of the terminal 20 can be concentrated on the easily-deformable portion 24 inside the resin portion 10. Therefore, a residual stress can be prevented from remaining outside the resin portion 10, and the residual stress can be received by the resin portion 10. Therefore, the positional accuracy of the terminal 20 after molding of the resin can be further improved.

In addition, in the present embodiment, the first portion 21 extends to inside the resin portion 10.

As a result, the injection pressure at the time of molding the resin can be received by the first portion 21. Therefore, deformation of the terminal 20 due to the injection pressure of the resin can be suppressed. Therefore, the positional accuracy of the terminal 20 after molding of the resin can be further improved.

In addition, in the present embodiment, in the insert-molded article 1, the area of the surface orthogonal to the plate thickness direction in the first portion 21 is larger outside the resin portion 10 than inside the resin portion 10. In the method for manufacturing the insert-molded article 1, in the supporting of each of the first portion 21 and the second portion 22 by the molding die 200 (supporting step), the first portion 21 is supported by the molding die 200 (a pair of support portions 202b) in the region having a larger area than the region to which the resin is supplied in the surface orthogonal to the injection direction D of the resin in the first portion 21.

As a result, in the first portion 21, the area supported by the molding die 200 can be increased with respect to the area receiving the injection pressure at the time of molding the resin, so that the positional accuracy of the terminal 20 can be easily improved.

In addition, in the present embodiment, the first portion 21 includes the internal cut-away part 21b (an example of a cut-away part or a protrusion) located inside the resin portion 10.

Therefore, the first portion 21 can be fixed in the extending direction of the terminal 20 by the resin portion 10. Therefore, the positional accuracy of the terminal 20 can be further improved.

In addition, in the present embodiment, the first portion 21 includes the external cut-away part 21a, which is an example of a cut-away part or a protrusion, located outside the resin portion 10.

Therefore, the first portion 21 can be supported in the extending direction (Y direction) of the terminal 20 at the external cut-away part 21a by the molding die 200. Therefore, the positional accuracy of the terminal 20 can be further improved. As a result, in the present embodiment, when the support of the first portion 21 in the plate thickness direction (X direction) by the molding die 200 (a pair of support portions 202b) and the support of the second portion 22 in the plate thickness direction (Z direction) by the molding die 200 are included, the molding die 200 can support the terminal 20 in six directions of the X direction (positive side and negative side), the Y direction (positive side and negative side), and the Z direction (positive side and negative side).

In addition, in the method for manufacturing the insert-molded article 1 according to the present embodiment, in the supplying and curing of the resin (supply and curing step), the narrow portion (for example, the easily-deformable portion 24) provided in the terminal 20 reduces the area orthogonal to the injection direction D of the resin in the portion of the terminal 20 to which the resin is supplied (for example, the area to be reduced is the region A illustrated in FIG. 3).

As a result, it is possible to suppress the deformation of the terminal 20 due to the injection pressure of the resin because the injection pressure of the resin is not received in the region A illustrated in FIG. 3. Therefore, the positional accuracy of the terminal 20 can be further improved.

Hereinafter, the invention described in the claims of the originally filed application will be additionally described.

### Supplementary Note 1

An insert-molded article including:
a resin portion; and
a terminal having both ends extending from the resin portion,
in which the terminal has higher rigidity at a first portion adjacent to the resin portion outside the resin portion and a second portion adjacent to the resin portion on a side opposite to the first portion than at a tip portion of the terminal on at least one end side.

### Supplementary Note 2

The insert-molded article according to Supplementary Note 1,
in which the terminal has a larger cross-sectional area orthogonal to an extending direction of the terminal at the first portion and the second portion than at the tip portion.

### Supplementary Note 3

The insert-molded article according to Supplementary Note 1,
in which the terminal includes, inside the resin portion, an easily-deformable portion that is more easily deformed than other adjacent portions of the terminal.

### Supplementary Note 4

The insert-molded article according to Supplementary Note 1,
in which the first portion extends to inside the resin portion.

### Supplementary Note 5

The insert-molded article according to Supplementary Note 4,
in which an area of a surface orthogonal to a plate thickness direction in the first portion is larger outside the resin portion than inside the resin portion.

### Supplementary Note 6

The insert-molded article according to Supplementary Note 4,
in which the first portion includes a cut-away part or a protrusion located inside the resin portion.

### Supplementary Note 7

The insert-molded article according to Supplementary Note 1,
in which the first portion includes a cut-away part or a protrusion located outside the resin portion.

### Supplementary Note 8

The insert-molded article according to Supplementary Note 1, further including a third portion between the first portion and the second portion, the third portion having a cross-sectional area made smaller than those of the first portion and the second portion by providing a cut-away part.

### Supplementary Note 9

The insert-molded article according to Supplementary Note 8, in which the third portion has lower rigidity than the first portion or the second portion.

### Supplementary Note 10

The insert-molded article according to Supplementary Note 9, in which the third portion is connected to the first portion and the second portion such that an extending direction of the first portion and an extending direction of the second portion are orthogonal to each other.

### Supplementary Note 11

The insert-molded article according to Supplementary Note 10, in which the second portion extends in a first direction and then extends in a second direction perpendicular to the first direction, so that a part of a portion extending in the second direction is exposed from the resin portion.

### Supplementary Note 12

A method for manufacturing an insert-molded article including a resin portion and a terminal having both ends extending from the resin portion, the method including:
supporting each of a first portion and a second portion of the terminal by a molding die, the first portion and the second portion having higher rigidity than a tip portion of the terminal on at least one end side; and
supplying a resin to the terminal between the first portion and the second portion in a state where the first portion and the second portion are supported by the molding die, and curing the resin.

### Supplementary Note 13

The method for manufacturing the insert-molded article according to Supplementary Note 12,
in which in the supporting,
the first portion is supported by the molding die in a region having a larger area than a region to which the resin is supplied in a surface orthogonal to an injection direction of the resin in the first portion.

### Supplementary Note 14

The method for manufacturing the insert-molded article according to Supplementary Note 12,
in which in the supplying and curing of the resin,
a narrow portion provided in the terminal reduces an area orthogonal to an injection direction of the resin in a portion of the terminal to which the resin is supplied.

As described above, the present invention can improve the positional accuracy of the terminal after molding of the resin in the insert-molded article and the method for manufacturing the insert-molded article. Therefore, it is useful for a semiconductor device or the like for which high positional accuracy of a terminal is required.

What is claimed is:

1. An insert-molded article, comprising:
a resin portion; and
a terminal having
a first portion extending in a first direction from the resin portion to be adjacent to the resin portion at a first side of the resin portion,
a second portion extending in a second direction different from the first direction from the resin portion to be adjacent to the resin portion at a second side of the resin portion that is different from the first side, and
a tip portion connected to one of the first and second portions, wherein the first and second portions have rigidities that are higher than a rigidity of the tip portion.

2. The insert-molded article according to claim 1, wherein the first and second portions of the terminal respectively have first and second cross-sectional areas in first and second planes respectively orthogonal to the first and second directions, that are greater than a cross-sectional area of the tip portion in a plane orthogonal to an extending direction of the tip portion.

3. The insert-molded article according to claim 1, wherein the first and second portions of the terminal include, inside the resin portion, an easily-deformable portion that is deformed with less power than power required to deform the rest of first and second portions of the terminal.

4. The insert-molded article according to claim 1, wherein the first portion also extends inside the resin portion.

5. The insert-molded article according to claim 4, wherein
the first portion has a plate shape, and
a third cross-sectional area of the first portion in a third plane parallel to a plate surface of the first portion is larger outside the resin portion than inside the resin portion.

6. The insert-molded article according to claim 4, wherein the first portion has a cut-away part or a protrusion that is located inside the resin portion.

7. The insert-molded article according to claim 1, wherein the first portion includes a cut-away part or a protrusion that is located outside the resin portion.

8. The insert-molded article according to claim 1, wherein the terminal further has a cut-away part between the first portion and the second portion, thereby forming a third portion that has cross-sectional areas in the first and second planes that are respectively smaller than the first and second cross-sectional areas of the first and second portions.

9. The insert-molded article according to claim 8, wherein the third portion has a rigidity lower than the rigidities of the first and second portions.

10. The insert-molded article according to claim 9, wherein the third portion is connected to the first portion and the second portion such that the first direction and the second direction are orthogonal to each other.

11. The insert-molded article according to claim 10, wherein the second portion includes a first-second portion and a second-second portion, the first-second portion extending in the second direction, the second-second portion extending in a third direction perpendicular to the second direction, a part of the second-second portion at a side thereof opposite to a side where the first-second portion is corrected is exposed from the resin portion.

12. A method for manufacturing an insert-molded article including a resin portion and a terminal, the method comprising:
supporting each of a first portion and a second portion of the terminal by a molding die, the first portion and the second portion extending from the resin portion in different directions, and having rigidities higher than a rigidity of a tip portion of the terminal that is connected to one of the first and second portions; and
supplying a resin into the colliding dies between the first portion and the second portion of the terminal in a state where the first portion and the second portion are supported by the molding die, and curing the resin.

13. The method for manufacturing the insert-molded article according to claim 12,
wherein in the supporting, the first portion is supported by the molding die in a region having an area greater than an area of a region to which the resin is supplied in a plane orthogonal to an injection direction of the resin in the first portion.

14. The method for manufacturing the insert-molded article according to claim 12,
wherein in the supplying and curing of the resin, a narrow portion provided in the terminal reduces an area of the terminal in a plane that is orthogonal to an injection direction of the resin and to which the resin is supplied.
